(19) United States
(12) Patent Application Publication
(10) Pub. No.: US 2010/0132997 A1
(43) Pub. Date: Jun. 3, 2010

(54) MULTILAYER WIRING SUBSTRATE AND METHOD FOR MANUFACTURING THE SAME

(76) Inventor: Takuya HANDO, Inuyama-shi (JP)

Correspondence Address: STITES & HARBISON PLLC, 1199 NORTH FAIRFAX STREET, SUITE 900, ALEXANDRIA, VA, 22314, US

(21) Appl. No.: 12/629,438

(22) Filed: Dec. 2, 2009

(30) Foreign Application Priority Data
Dec. 3, 2008 (JP) JP 2008-308445

(51) Int. Cl. H01R 12/00; H05K 3/10

(52) U.S. Cl. 174/262; 29/850; 29/846

(57) ABSTRACT

A multilayer wiring substrate is manufactured through a recess forming step, a gold-diffusion-prevention-layer forming step, a terminal forming step, resin-insulating-layer forming step, a conductor forming step, and a metal-layer removing step. In the recess forming step, a copper foil layer is half-etched so as to form recesses. In the gold-diffusion-prevention-layer forming step, a gold diffusion prevention layer is formed in each recess. In the terminal forming step, a gold layer, a nickel layer, and a copper layer are stacked in sequence on the gold diffusion prevention layer to thereby form a surface connection terminal. In the resin-insulating-layer forming step, a resin insulating layer is formed, and, in the conductor forming step, via conductors and conductor layers are formed. In the metal-layer removing step, the copper foil layer and the gold diffusion prevention layer are removed so that the gold layer projects from the main face of the laminated structure.

### CROSS-REFERENCE TO RELATED APPLICATIONS

This application is based on and claims priority to Japanese Patent Application No. JP2008-308445, filed Dec. 3, 2008, which is hereby incorporated by reference in its entirety.

### BACKGROUND OF THE INVENTION

1. Field of the Invention

The present invention relates to a multilayer wiring substrate having a laminated structure composed of conductor layers and resin insulating layers alternately stacked, and to a method for manufacturing the same.

2. Description of Related Art

In recent years, semiconductor integrated circuit elements (IC chips) used as microprocessors of computers or the like have been enhanced in speed and function more and more, and, thus, IC chips tend to have an increased number of terminals and a reduced inter-terminal pitch. In general, a large number of terminals are densely disposed in an array on the bottom surface of an IC chip. Such a group of terminals are flip-chip connected to a group of terminals on the motherboard. However, since the inter-terminal pitch differs greatly between the IC chip side terminal group and the motherboard side terminal group, difficulty is encountered in connecting the IC chip directly onto the motherboard. Therefore, in general, a semiconductor package including an IC chip mounted on an IC-chip mounting wiring substrate is fabricated, and is then mounted on a motherboard (see, for example, Japanese Patent Application Laid-Open (kokai) No. 2002-26500 (FIG. 1, etc.)).

Notably, an IC-chip mounting wiring substrate is manufactured, for example, through the steps described below. First, a copper foil layer is disposed on a support substrate, and a predetermined mask is disposed on the copper foil layer. Subsequently, a gold layer, a nickel layer, and a copper layer are stacked, in this sequence, on portions of the copper foil layer exposed from the opening portions of the mask. As a result, surface connection terminals, on which solder bumps for connection of an IC chip are disposed, are formed (terminal forming step). Subsequently, after the mask is removed, a resin insulating layer for covering the surface connection terminals is formed on the support substrate (resin-insulating-layer forming step). Further, via conductors connected to the surface connection terminals are formed in the resin insulating layer. Conductor layers and resin insulating layers are alternately stacked so as to form a laminated structure. After that, the support substrate and the copper foil layer are removed (removal step), whereby a multilayer wiring substrate having a laminated structure can be obtained.

However, since the gold layer comes into contact with the copper foil layer in the terminal forming step, in some cases, gold diffuses into copper foil layer upon application of heat during the subsequent formation of the laminated structure. In such a case, gold, which exhibits excellent joinability with solder, does not remain on the surface connection terminals. Therefore, when solder bumps are formed on the surface connection terminals after the removal step, difficulty arises in joining the solder bumps to the surface connection terminals. Consequently, the reliability of the connection between the surface connection terminals and the IC chip drops, and, thus, the reliability of the multilayer wiring substrate drops.

### BRIEF SUMMARY OF THE INVENTION

The present invention has been accomplished in order to solve the above-described problem, and its object is to provide a method of manufacturing a multilayer wiring substrate which can improve reliability by improving the reliability of the connection between surface connection terminals and a chip component. Another object of the present invention is to provide a multilayer wiring substrate having surface connection terminals which can improve the reliability of connection between the surface connection terminals and a chip component.

A means (first means) for solving the above-described problem is a method for manufacturing a multilayer wiring substrate which has a laminated structure composed of a plurality of conductor layers and a plurality of resin insulating layers stacked alternately and in which a plurality of surface connection terminals to which terminals of a chip component are to be surface-connected are formed on a main face of the laminated structure, and a plurality of via conductors connected to the plurality of surface connection terminals are formed in the resin insulating layers. The method comprises a recess forming step of disposing an etching mask on a copper foil layer, which will be removed later, and half-etching portions of the copper foil layer exposed from opening portions of the mask, so as to form recesses; a gold-diffusion-prevention-layer forming step of forming, in the recesses, a gold diffusion prevention layer for preventing gold from diffusing into the copper foil layer; a terminal forming step of layering a gold layer, a nickel layer, and a copper layer in sequence on the gold diffusion prevention layer, thereby forming the plurality of surface connection terminals; a resin-insulating-layer forming step of forming, after removal of the mask, a resin insulating layer which covers the surface connection terminals; a conductor forming step of forming the via conductors in each of the plurality of resin insulating layers and forming a conductor layer of said plurality of conductor layers on each of the resin insulating layers; and a metal-layer removing step of removing the copper foil layer and the gold diffusion prevention layer after forming the via conductors so that the gold layer of the plurality of surface connection terminals projects from the main face.

According to the invention of the first means, after the gold diffusion prevention layer is formed on the copper foil layer in the gold-diffusion-prevention-layer forming step, the gold layer is stacked on the gold diffusion prevention layer in the terminal forming step. Since the gold layer does not come into direct contact with the copper foil layer, gold does not diffuse into the copper foil layer. As a result, gold, which is excellent in joinability with solder, remains on the surfaces of the surface connection terminals without fail. Therefore, when solder bumps are formed on the surface connection terminals after the metal-layer removing step, the surface connection terminals and the solder bump can be reliably joined together via the gold layer. Accordingly, the reliability of connection between the surface connection terminals and terminals of a chip component connected to the surface connection terminals via solder bumps can be increased, and, thus, the reliability of the multilayer wiring substrate can be improved.

Moreover, since the gold diffusion prevention layer and the gold layer are formed in the recesses formed in the copper foil layer, the gold layer of the surface connection terminals projects from the main face of the laminated structure without fail when the copper foil layer and the gold diffusion prevention layer are removed in the metal-layer removing step. As a result, when solder bumps are formed on the surface connection terminal, the area of contact between each surface connection terminal and a corresponding solder bump becomes larger, as compared with a case where the gold layer is not projected, whereby the strength of bonding between the surface connection terminal and the solder bump can be increased, and the reliability of connection between the surface connection terminals and the terminals of the chip component can be improved further.

Notably, the above-described multilayer wiring substrate may be properly selected in consideration of cost, machinability, insulation property, mechanical strength, etc. The multilayer wiring substrate which is manufactured by the method of the present invention has a laminated structure composed of conductor layers and resin insulating layers stacked alternately, and is configured such that a plurality of surface connection terminals to which terminals of a chip component are to be surface-connected are formed on a main face of the laminated structure, and a plurality of via conductors connected to the plurality of surface connection terminals are formed in the resin insulating layers.

Examples of the chip component include capacitors, semiconductor integrated circuit elements (IC chips), and MEMS (Micro Electro Mechanical Systems) elements manufactured through a semiconductor manufacturing process. Examples of IC chips include DRAM (Dynamic Random Access Memory) and SRAM (Static Random Access Memory). The “semiconductor integrated circuit element” refers to an element which is mainly used as a microprocessor of a computer or the like. Further, other examples of the chip component include chip transistors, chip diodes, chip resistors, chip capacitors, and chip coils.

Incidentally, in recent years, in order to cope with an increase in operation speed of a semiconductor integrated circuit element, a signal frequency within a high-frequency band is employed. In such a case, if a multilayer wiring substrate includes a core substrate, wiring passing through the core substrate produces a large inductance, resulting in generation of a transmission loss of high frequency signals and/or occurrence of a malfunction of a circuit. Therefore, the core substrate prevents the semiconductor integrated circuit element from operating at a higher speed. In view of this, preferably, the multilayer wiring substrate does not have a core substrate, and the plurality of via conductors are formed in the resin insulating layers such that the diameter of each via conductor increases toward the same direction in the respective layer. That is, preferably, the multilayer wiring substrate is a coreless wiring substrate which is mainly formed of the resin insulating layers of the same configuration, and the conductor layers of the resin insulating layers are connected together only through the via conductors whose diameter increases toward the same direction. When such a configuration is employed, the length of wiring can be shortened through elimination of a relatively thick core substrate. Thus, a transmission loss of high-frequency signals can be reduced, whereby the semiconductor integrated circuit element can be operated at a higher speed.

A method of manufacturing a multilayer wiring substrate according to the first means will next be described.

In the recess forming step, an etching mask is disposed on a copper foil layer, which will be removed later, and portions of the copper foil layer exposed from opening portions of the mask are half-etched so as to form recesses.

Preferably, the depth of the recesses is greater than the sum of a thickness of the gold diffusion prevention layer and a thickness of a gold layer. In this case, when the copper foil layer is removed through later performance of the metal-layer removing step, the surface connection terminals formed in the recesses project from the main face of the laminated structure without fail. Thus, the surface area of each surface connection terminal increases. Therefore, when solder bumps are formed on the surface connection terminals, the surface connection terminals and the solder bumps are bonded together with an increased bonding strength. Further, since a metal foil layer for the recess formation is not required to be provided separately from the copper foil layer, the manufacturing cost of the multilayer wiring substrate can be lowered.

In the subsequent gold-diffusion-prevention-layer forming step, a gold diffusion prevention layer for preventing gold from diffusing into the copper foil layer is formed in the recesses.

No limitation is imposed on the material of the gold diffusion prevention layer, so long as a selected material is a metal which can prevent diffusion of gold. Preferably, the gold diffusion prevention layer is formed of a metal selected from nickel, palladium, and titanium. More preferably, the gold diffusion prevention layer is formed of nickel. In this case, the gold diffusion prevention layer can be formed at a lower cost as compared with the case where the gold diffusion prevention layer is formed of a material other than nickel.

The gold diffusion prevention layer is formed by a known process, such as a subtractive process, a semi-additive process, or a full-additive process. Specifically, for example, etching of metal foil, electroless plating, electro plating, or the like process is applied. Notably, preferably, the gold diffusion prevention layer is a nickel plating layer whose thickness falls within a range of 1 μm to 5 μm inclusive. If the thickness of the gold diffusion prevention layer is less than 1 μm, gold may diffuse into the copper foil layer, because the gold diffusion prevention layer becomes likely to break with the result that the gold layer comes into contact with the copper foil layer. Meanwhile, if the thickness of the gold diffusion prevention layer is greater than 5 μm, since the gold diffusion prevention layer occupies the greater part of the interior of each recess, and, thus, the area which is occupied by the surface connection terminal in each recess decreases. As a result, the projection amount of the gold layer of the surface connection terminal as measured from the main face of the laminated structure decreases. Therefore, when solder bumps are formed on the surface connection terminals, each solder bump comes into contact with the corresponding surface connection terminal via a reduced contact area. Therefore, the strength of bonding between the solder bump and the corresponding surface connection terminal drops, whereby the reliability of connection between the surface connection terminals and the terminals of the chip component may drops.

In the subsequent terminal forming step, a gold layer, a nickel layer, and a copper layer are stacked in this sequence on the gold diffusion prevention layer so as to form the plurality of surface connection terminals. The gold layer, the nickel layer, and the copper layer are formed by a known method, such as a subtractive process, a semi-additive process, or a full-additive process. Specifically, for example, etching of metal foil (gold foil, nickel foil, copper foil), electroless plating (electroless gold plating, electroless nickel plating, electroless copper plating), electro plating (electro gold plating, electro nickel plating, electro copper plating), or a like process is applied. Notably, the gold layer, the nickel layer, and the copper layer may be formed through printing of electrically conductive paste or the like.

In the subsequent resin-insulating-layer forming step, the resin insulating layer which covers the surface connection terminals is formed after removal of the mask. The resin insulating layer can be properly selected in consideration of insulation property, heat resistance, moisture resistance, etc. Examples of a polymeric material used for forming the resin insulating layer include thermosetting resins, such as epoxy resin, phenol resin, urethane resin, silicone resin, and polyimide resin; thermoplastic resins, such as polycarbonate resin, acrylic resin, polyacetal resin, and polypropylene resin; etc. Alternatively, there may be used a composite material of any of these resins and glass fibers (glass woven fabric or glass unwoven fabric) or organic fibers such as polyamide fibers; or a resin-resin composite material formed by impregnating a three-dimensional network fluorine-based resin matrix, such as an interconnected porous PTFE, with a thermosetting resin, such as epoxy resin.

In the subsequent conductor forming step, the via conductors are formed in each of the resin insulating layers, and the conductor layer is formed on each of the resin insulating layers. The conductor layer is mainly formed of copper through a known process such as a subtractive process, a semi-additive method, or a full-additive method. Specifically, for example, etching of copper foil, electroless copper plating, electro copper plating, or the like process is applied. Notably, the conductor layer may be formed through etching of a thin film formed by spattering, CVD, or the like; or through printing of electrically conductive paste or the like.

In the subsequent metal-layer removing step, the copper foil layer and the gold diffusion prevention layer are removed after the conductor layer forming step, whereby the gold layer of the plurality of surface connection terminals project from the main face. Thus, a multilayer wiring substrate can be obtained.

Notably, preferably, the gold diffusion prevention layer is formed of a metal which can be removed through etching. In this case, since the copper foil layer can be removed together with the gold diffusion prevention layer when etching is performed, the production efficiency of the multilayer wiring substrate can be increased.

Another means (second means) for solving the above-described problem is a multilayer wiring substrate having a laminated structure composed of conductor layers and resin insulating layers stacked alternately and in which a plurality of surface connection terminals to which terminals of a chip component are to be surface-connected are formed on a main face of the laminated structure, and a plurality of via conductors connected to the plurality of surface connection terminals are formed in the resin insulating layers, wherein each of the plurality of surface connection terminals is composed of a copper layer, a nickel layer, and a gold layer stacked in sequence; and the gold layer projects from the main face of the laminated structure.

According to the invention of the above-described second means, since the gold layer of the plurality of surface connection terminals projects from the main face of the laminated structure, the surface area of each surface connection terminal increases as compared with the case where the gold layer is not projected from the main face. In particular, when the projection amount of the gold surface as measured with the main surface used as a reference is set to 5 μm or more, the surface area of each surface connection terminal increases more reliably. Thus, when solder bumps are formed on the surface connection terminals, the strength of bonding between each surface connection terminal and a corresponding solder bump can be increased, and the reliability of connection between the surface connection terminals and the terminals of the chip component can be improved further.

Notably, preferably, the plurality of via conductors increase in diameter toward a back face of the laminated structure, and the plurality of surface connection terminals are connected to the smaller-diameter-side end faces of the via conductors. In this case, since the diameter of the via conductors increases toward the back face of the laminated structure, there can be increased the strength of bonding between the outer circumferential surfaces of the via conductors and the inner wall surfaces of via holes in which the via conductors are formed. Accordingly, even when the multilayer wiring substrate warps and excessively stress acts on the via conductors, there can be prevented occurrence of problems such as bonding failure of the via conductors and coming off of the via conductor toward the smaller-diameter-side end face. Thus, production yield of the multilayer wiring substrate can be improved.

Other features and advantages of the invention will be set forth in, or apparent from, the detailed description of the exemplary embodiment(s) of the invention found below.

### BRIEF DESCRIPTION OF THE DRAWINGS

FIG. 1 is a schematic cross sectional view of a semiconductor package including an exemplary multilayer wiring substrate according to the invention.

FIG. 2 is a main-portion cross sectional view of the multilayer wiring substrate of FIG. 1.

FIG. 3 is a main-portion cross sectional view including a terminal pad and a via conductor of the exemplary multilayer wiring substrate of FIG. 1.

FIG. 4 is a side sectional view including a laminated metal sheet disposed on each of opposite faces of a support substrate at a step of a method of manufacturing the exemplary multilayer wiring substrate of FIG. 1.

FIG. 5 is a side sectional view including a dry film, which serves as an etching mask, laminated on a copper foil layer at a step of the method of manufacturing the exemplary multilayer wiring substrate of FIG. 1.

FIG. 6 is a side sectional view including opening portions formed in the dry film at predetermined positions thereof so as to expose portions of the copper foil layer at a step of the method of manufacturing the exemplary multilayer wiring substrate of FIG. 1.

FIG. 7 is an enlarged side sectional view including an opening portion of FIG. 6.

FIG. 8 is an side sectional view including a recess formed in a portion of the copper foil layer at a step of the method of manufacturing the exemplary multilayer wiring substrate of FIG. 1.

FIG. 9 is a side sectional view including the recess of FIG. 8 having a gold diffusion prevention layer formed on an inner wall surface thereof at a step of the method of manufacturing the exemplary multilayer wiring substrate.

FIG. 10 is a side sectional view including terminal pads formed in the opening portions of FIG. 6. at a step of the method of manufacturing the exemplary multilayer wiring substrate.

FIG. 11 is an enlarged side sectional view including a terminal pad of FIG. 10.

FIG. 12 is a side sectional view including the terminal pads of FIG. 10 following removal of a dry film at a step of the method of manufacturing the exemplary multilayer wiring substrate.

FIG. 13 is an enlarged side sectional view including a terminal pad of FIG. 12.

FIG. 14 is a side sectional view including a fourth resin insulating layer which cover the terminal pad of FIG. 12 at a step of the method of manufacturing the exemplary multilayer wiring substrate.

FIG. 15 is an enlarged side sectional view including the fourth resin insulating layer of FIG. 14.

FIG. 16 is a side sectional view including via holes formed in the fourth resin insulating layer of FIG. 14 at a step of the method of manufacturing the exemplary multilayer wiring substrate.

FIG. 17 is a side sectional view including via conductors formed in the via holes of FIG. 16 at a step of the method of manufacturing the exemplary multilayer wiring substrate.

FIG. 18 is an enlarged side sectional view including a via conductor of FIG. 17.

FIG. 19 is a side sectional view including a laminate at a step of the method of manufacturing the multilayer wiring substrate of FIG. 1.

FIG. 20 is a side sectional view including the laminate of FIG. 19 in which wiring stacked portions are connected to the support substrate only through laminated metal sheets, at a step of the method of manufacturing the exemplary multilayer wiring substrate.

FIG. 21 is a side sectional view including the laminate of FIG. 20 in which the wiring stacked portions are separated from the support substrate, at a step of the method of manufacturing the exemplary multilayer wiring substrate.

FIG. 22 is a side sectional view including a wiring stacked portion of FIG. 21 at a step of the method of manufacturing the exemplary multilayer wiring substrate.

FIG. 23 is a side sectional view including the terminal pads projecting from a main face the wiring stacked portion of FIG. 22, at a step of the method of manufacturing the exemplary multilayer wiring substrate.

FIG. 24 is an enlarged side sectional view including a gold plating layer of a terminal pad of FIG. 23.

### DETAIL DESCRIPTION OF EXEMPLARY EMBODIMENTS OF THE INVENTION

An exemplary embodiment of the present invention will now be described in detail with reference to the drawings.

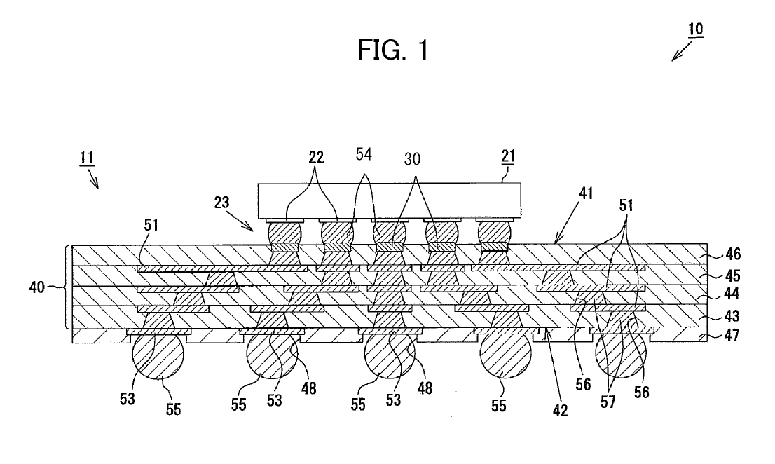

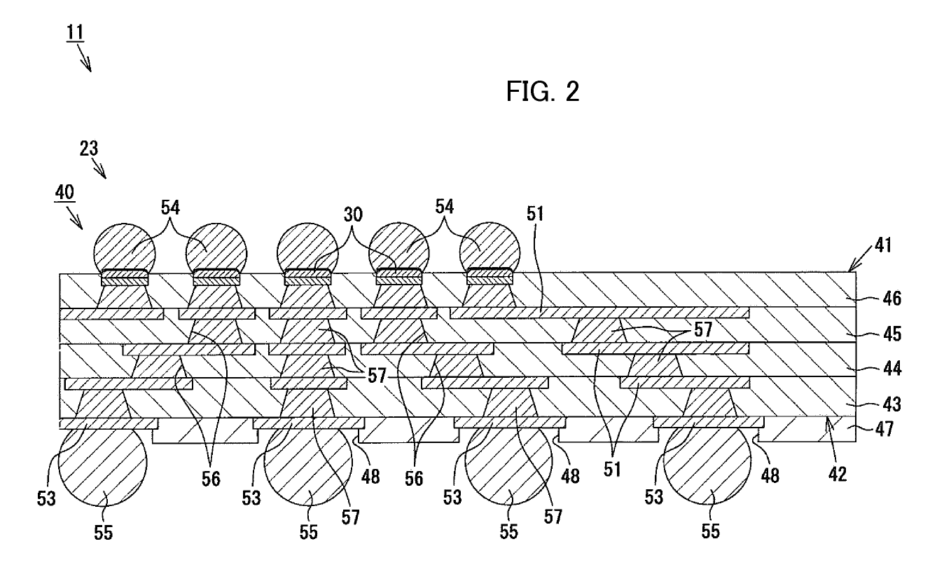

As shown in FIGS. 1 and 2, a semiconductor package 10 of the present embodiment is of a BGA (ball grid array) type, and is composed of a multilayer wiring substrate 11 and a IC chip 21 (chip component), which is a semiconductor integrated circuit element. Notably, the type of the semiconductor package 10 is not limited to BGA, and may be PGA (pin grid array), LGA (land grid array), or the like. The IC chip 21 is preferably formed of silicon whose coefficient of thermal expansion is 4.2 ppm/° C. and assumes the form of a rectangular flat plate whose size is 15.0 mm (length)×15.0 mm (width)×0.8 mm (thickness).

Meanwhile, the exemplary multilayer wiring substrate 11 does not have a core substrate, and has a wiring stacked portion 40 (laminated structure) composed of conductor layers 51 formed of copper and four resin insulating layers 43, 44, 45, and 46, which are alternately stacked with the conductor layers 51. The wiring stacked portion 40 of the present embodiment preferably assumes a generally rectangular shape as viewed from above, and has a size of 50.0 mm (length)×50.0 mm (width)×0.4 mm (thickness). In the present embodiment, the coefficient of thermal expansion of the resin insulating layers 43 to 46 is about 10 to 60 ppm/° C. (specifically, about 20 ppm/° C.). Notably, the coefficient of thermal expansion of the resin insulating layers 43 to 46 refers to the average value of measurement values between 30° C. and glass transition temperature (Tg).

As shown in FIGS. 1 and 2, terminal pads 30 (surface connection terminals) are disposed in an array on a main face 41 of the wiring stacked portion 40 (on the surface of the fourth resin insulating layer 46). As shown in FIG. 3, each of the terminal pads 30 has a laminated structure in which a copper plating layer 31 (copper layer), a nickel plating layer 32 (nickel layer), and a gold plating layer 33 (gold layer) are stacked in this sequence. The thickness of the copper plating layer 31 is set to 10 μm, the thickness of the nickel plating layer 32 is set to fall within a range of 7 μm to 20 μm inclusive (in the present embodiment, 7 μm), and the thickness of the gold plating layer 33 is set to 0.4 μm. Further, a portion (in the present embodiment, an upper half) of the nickel plating layer 32 and the entire gold plating layer 33 project from the main face 41 of the wiring stacked portion 40. The gold plating layer 33 covers the entirety of the projecting portion of the nickel plating layer 32 (specifically, the top surface and a portion of the side surface of the nickel plating layer 32). Notably, in the present embodiment, the projection amount (the maximum value thereof) of the nickel plating layer 32 as measured with the main face 41 used as a reference is set to 5.0 μm, and the projection amount (the maximum value thereof) of the gold plating layer 33 as measured with the main face 41 used as a reference is set to 5.4 μm.

A plurality of solder bumps 54 are disposed on the surfaces of the terminal pads 30. Terminals 22 of the IC chip 21 are surface-connected to the solder bumps 54. The IC chip 21 is mounted on the main face 41 of the wiring stacked portion 40. Notably, a region where the terminal pads 30 and the solder bumps 54 are formed is an IC-chip mounting region 23 in which the IC chip 21 can be mounted.

Meanwhile, as shown in FIGS. 1 and 2, pads 53 for BGA are disposed in an array on the back face 42 of the wiring stacked portion 40 (on the lower surface of the first resin insulating layer 43). The pads 53 for BGA have a layered structure in which a nickel plating layer and a gold plating layer are stacked on a copper terminal in this sequence. Further, substantially the entirety of the lower surface of the resin insulating layer 43 is covered with a solder resist layer 47. Opening portions 48 for exposing the pads 53 for BGA are formed in the solder resist layer 47 at predetermined positions thereof. A plurality of solder bumps 55 for motherboard connection are disposed on the surfaces of the pads 53 for BGA, and the wiring stacked portion 40 is mounted on an unillustrated motherboard via the solder bumps 55.

As shown in FIGS. 1 to 3, each of the resin insulating layers 43 to 46 has via holes 56 and via conductors 57 formed therein. The via holes 56, each assuming the form of a truncated cone, are formed through drilling performed for each of the resin insulating layers 43 to 46 by use of a YAG laser or carbon dioxide gas laser. The via conductors 57 are conductors whose diameter increases toward the back face 42 of the wiring stacked portion 40 (downward in FIG. 1), and establish electrical connection among the conductor layers 51, the terminal pads 30, and the pads 53 for BGA. The terminal pads 30 are connected to the smaller-diameter-side end faces 58 of the via conductors 57 (see FIG. 3).

Next, a method for manufacturing the exemplary multilayer wiring substrate 11 will be described.

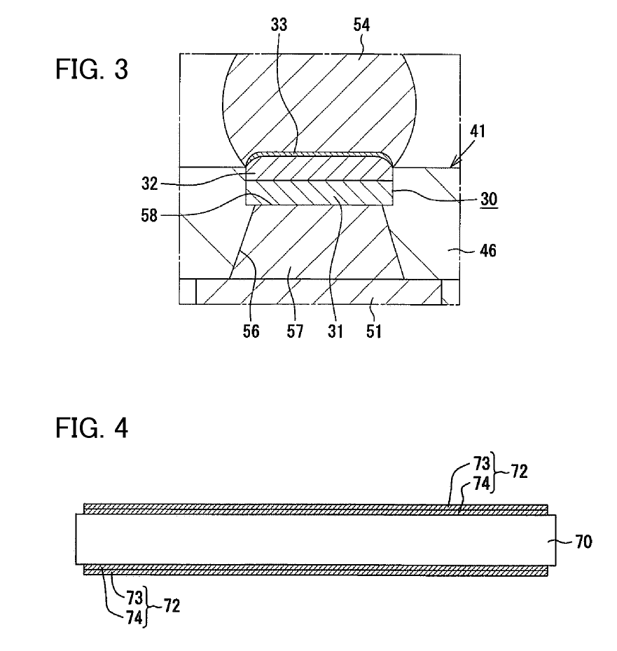

The present embodiment employs a method in which a support substrate (glass epoxy substrate or the like) having a sufficient strength is prepared, and the conductor layers 51 and the resin insulating layers 43 to 46 of the multilayer wiring substrate 11 (the wiring stacked portion 40) are built up on the support substrate. FIGS. 4 to 24, which are explanatory views illustrating the manufacturing method, show the resin insulating layers 43 to 46, conductor layers 51, etc., which are formed on the upper surface and lower surface of the support substrate 70.

Specifically, as shown in FIG. 4, a laminated metal sheet 72 is disposed on each of opposite faces of the support substrate 70. Each of the laminated metal sheets 72 is composed of two copper foil layers 73 and 74 separably bonded together. Specifically, each laminated metal sheet 72 is formed by laminating the copper foil layers 73 and 74 with metal plating (e.g., chromium plating) interposed therebetween.

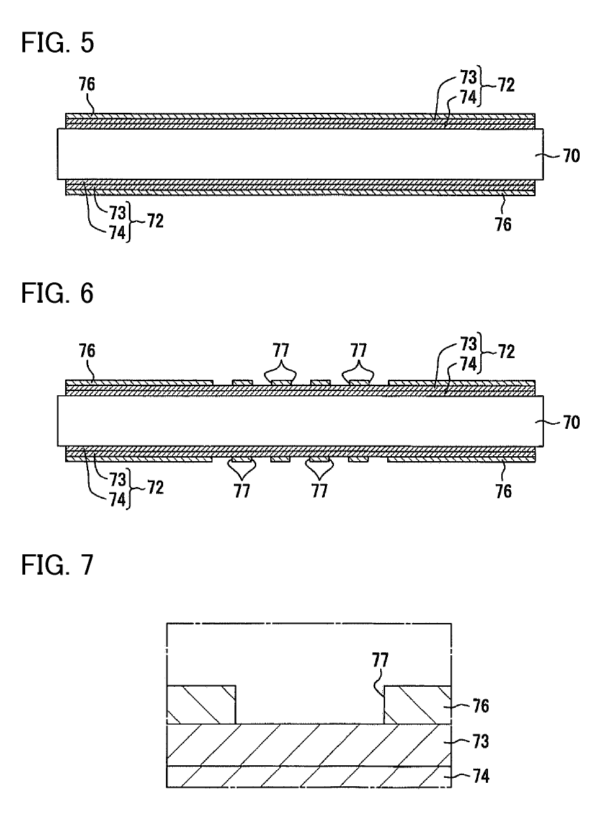

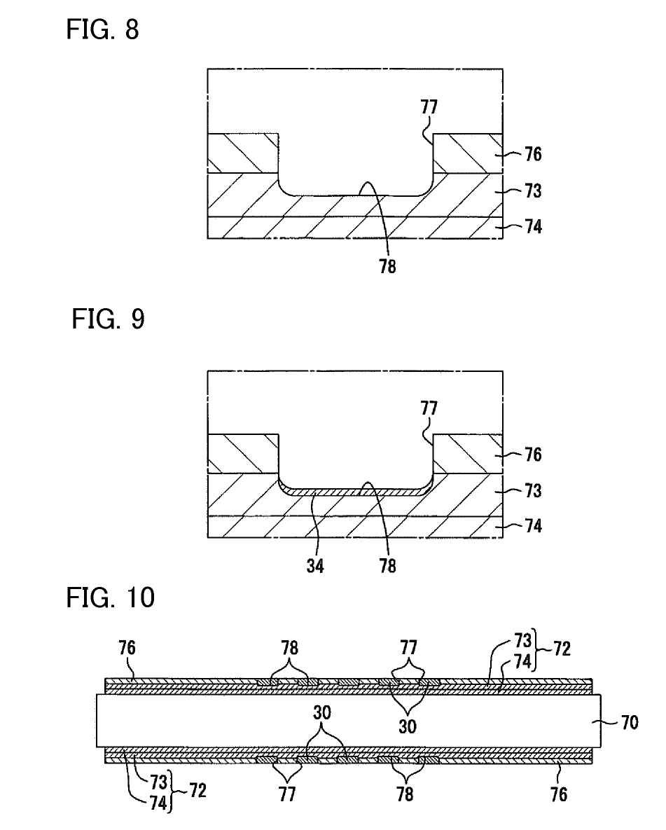

In a subsequent recess forming step, a dry film 76 (thickness: 12 μm), which serves as an etching mask, is laminated on the copper foil layer 73 (see FIG. 5). Next, through performance of exposure and development, opening portions 77 (diameter: 100 μm) are formed in the dry film 76 at predetermined positions thereof so as to expose portions of the copper foil layer 73 (see FIGS. 6 and 7). The portions of the copper foil layer 73 exposed from the opening portion 77 are half-etched, whereby recesses 78 having a depth of 8 μm are formed (see FIG. 8).

In a subsequent gold-diffusion-prevention-layer forming step, nickel plating is performed on inner wall surfaces of the recesses 78 through the dry film 76. As a result, a gold diffusion prevention layer 34 having a thickness of about 2 to 3 μm (in the present embodiment, 2.6 μm) is formed on the inner wall surface of each recess 78 (see FIG. 9). That is, the gold diffusion prevention layer 34 is a nickel plating layer formed of a metal (nickel) which can be removed through etching. Notably, the gold diffusion prevention layer 34 prevents gold contained in the gold plating layer 33 from diffusing into copper which constitutes the copper foil layer 73.

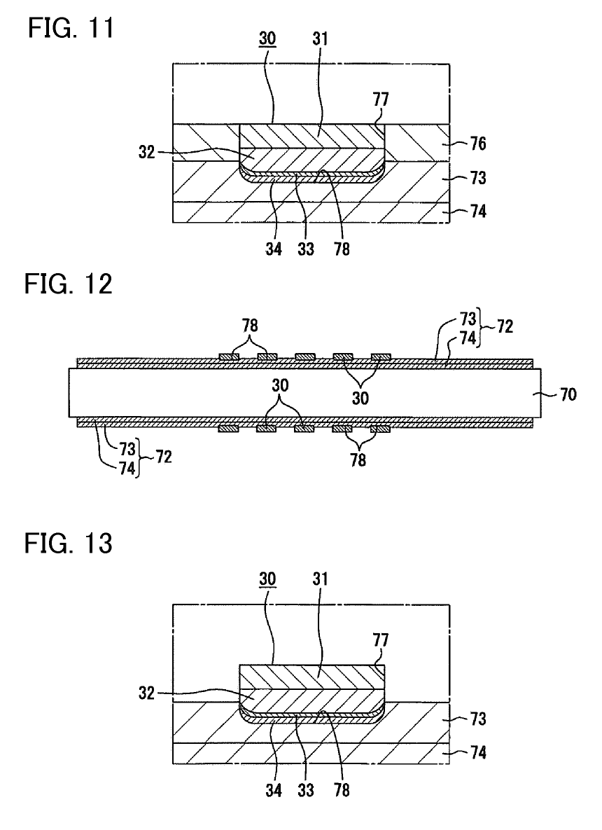

In a subsequent terminal forming step, the gold plating layer 33, the nickel plating layer 32, and the copper plating layer 31 are stacked in this sequence on the gold diffusion prevention layer 34, whereby the terminal pads 30 are formed (see FIGS. 10 and 11). More specifically, gold plating is performed on the gold diffusion prevention layer 34 via the dry film 76, whereby the gold plating layer 33 is formed on the gold diffusion prevention layer 34. Notably, the depth (8 μm) of the recess 78 is greater than the sum (3 μm) of the thickness (2.6 μm) of the gold diffusion prevention layer 34 and the thickness (0.4 μm) of the gold plating layer 33. Next, nickel plating is performed on the gold plating layer 33 through the dry film 76, whereby the nickel plating layer 32 is formed on the gold plating layer 33. Moreover, copper plating is performed on the nickel plating layer 32 through the dry film 76, whereby the copper plating layer 31 is formed on the nickel plating layer 32. Thus, the terminal pads 30 are completed. After that, the dry film 76 is removed so that the terminal pads 30 project from the surface of the copper foil layer 73 (see FIGS. 12 and 13).

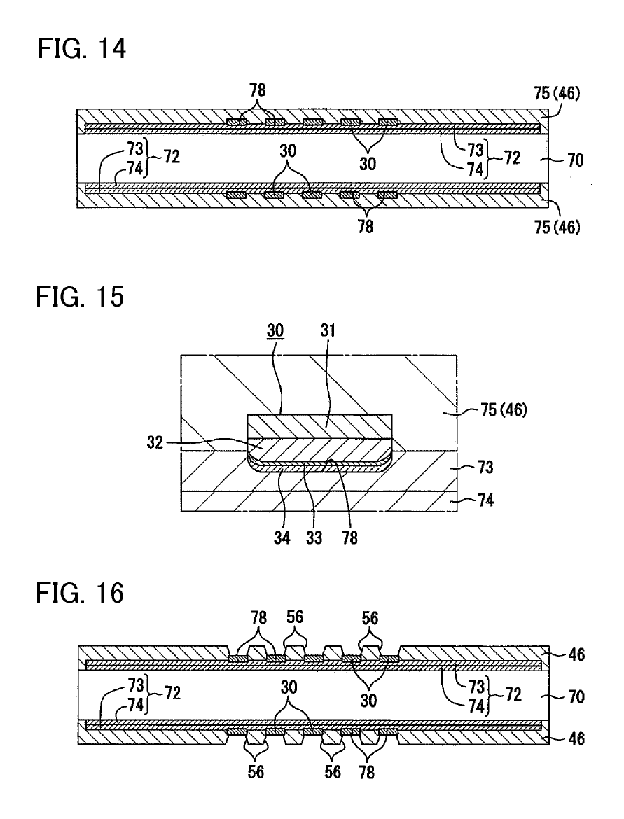

In a subsequent resin-insulating-layer forming step, sheet-like insulating resin base materials 75 are laminated on both the laminated metal sheets 72; pressure and heat are applied to the resultant laminate under vacuum by use of a vacuum-bonding hot press machine (not shown); and the laminate is cured, whereby the fourth resin insulating layers 46, which cover the terminal pads 30, are formed (see FIGS. 14 and 15). As shown in FIG. 16, through laser machining, the via holes 56 are formed in the resin insulating layers 46 at predetermined positions thereof, and desmearing is performed so as to remove smears within the via holes 56.

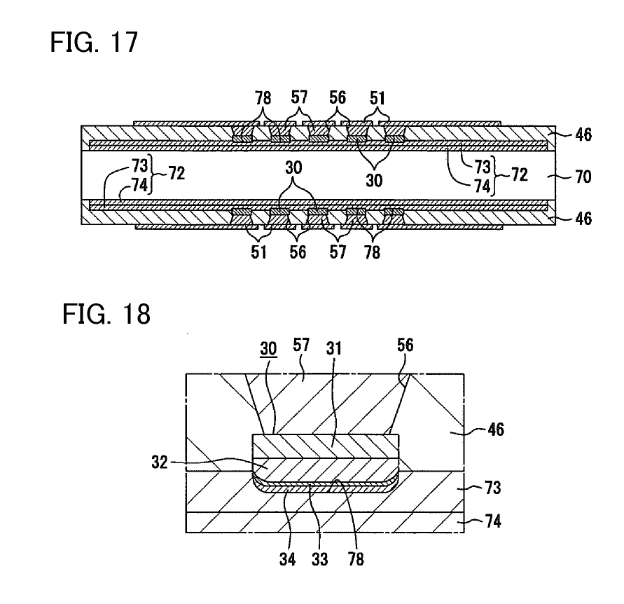

In a subsequent conductor forming step, electroless copper plating and electro copper plating are performed in accordance with a conventionally known method, whereby the via conductors 57 are formed within the via holes 56 (see FIGS. 17 and 18). At that time, the smaller-diameter-side end faces 58 (see FIG. 3) of the via conductors 57 formed in the resin insulating layers 46 are connected to the terminal pads 30. Further, through performance of etching in accordance with a conventionally known method (e.g., semiadditive method), a conductor layer 51 of a predetermined pattern is formed on each of the resin insulating layers 46 (see FIG. 17).

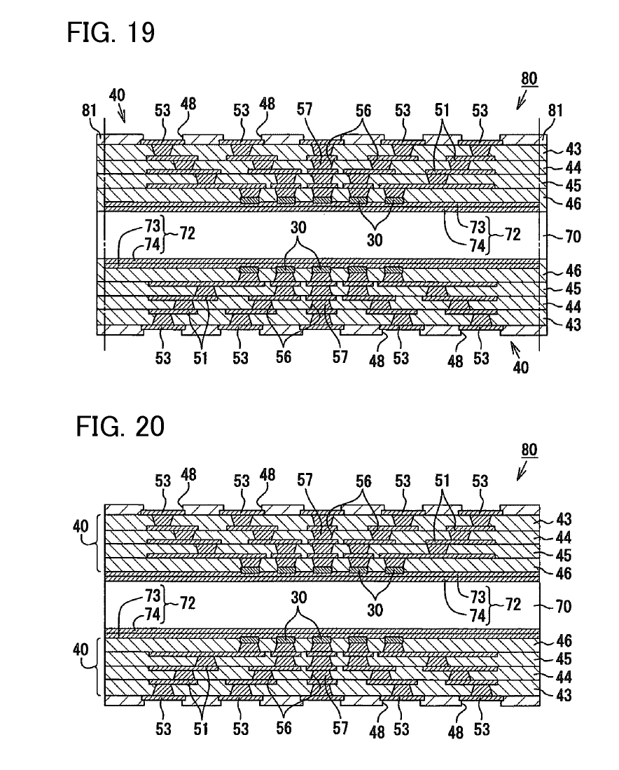

The first through third resin insulating layers 43 to 45 and the remaining conductor layers 51 are formed by the same method as the method employed for formation of the above-described fourth resin insulating layers 46 and the above-mentioned conductor layers 51, and are stacked on the resin insulating layers 46. Subsequently, a photosensitive epoxy resin is applied onto each resin insulating layer 43 having the pads 53 for BGA, and is cured, whereby a solder resist layer 47 is formed. Next, opening portions 48 are formed in the solder resist layer 47 through performance of exposure and development with a mask having a predetermined pattern disposed on the solder resist layer 47 (see FIG. 2). As a result of performance of the above-described manufacturing steps, there is formed a laminate 80 in which the laminated metal sheet 72, the resin insulating layers 43 to 46, and the conductor layers 51 are stacked on each of opposite sides of the support substrate 70 (see FIG. 19). Notably, as shown in FIG. 19, a portion of the laminate 80 located on each laminated metal sheet 72 serves as a wiring stacked portion 40.

Subsequently, the laminate 80 is cut by use of a dicing machine (not shown) so as to remove a portion of the laminate 80 around the wiring stacked portions 40. At that time, the wiring stacked portions 40 are cut together with the support substrate 70 at the boundary between the wiring stacked portions 40 and a peripheral portion 81 around the wiring stacked portions 40 (see the chain line of FIG. 19). As a result of this cutting, outer edge portions of the laminated metal sheet 72 buried in the resin insulating layers 46 are exposed to the outside. That is, through removal of the peripheral portion 81, the area where the support substrate 70 and the resin insulating layers 46 are bonded together is lost. As a result, there is created a state in which the wiring stacked portions 40 are connected to the support substrate 70 only through the laminated metal sheets 72 (see FIG. 20).

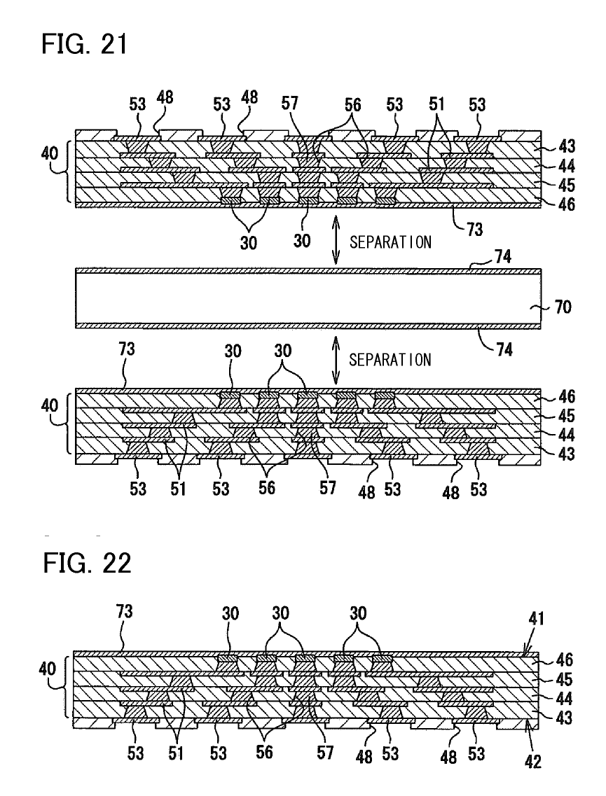

Next, the laminate 80 is separated into the wiring stacked portions 40 and the support substrate 70, whereby the copper foil layers 73 are exposed. Specifically, the two copper foil layers 73 and 74 of each laminated metal sheet 72 are separated from each other at the boundary therebetween so as to separate the wiring stacked portions 40 from the support substrate 70 (see FIGS. 21 and 22).

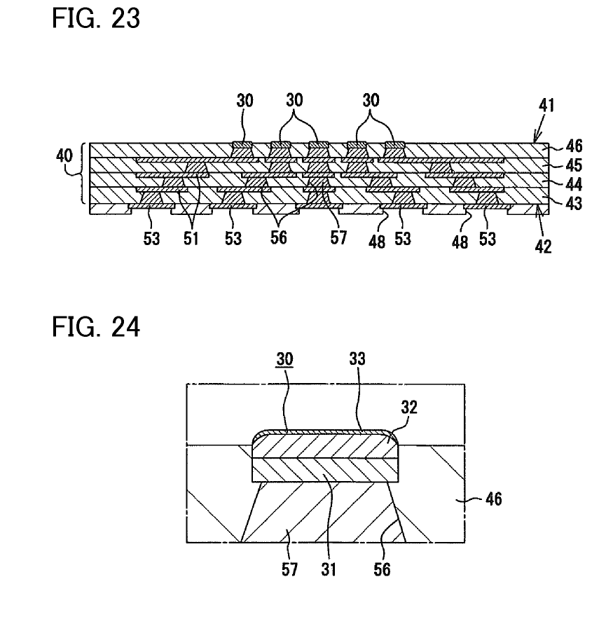

In a subsequent metal-layer removing step, etching is performed on the copper foil layer 73 on the main face 41 of each wiring stacked portion 40 (the resin insulating layer 46) so as to remove the copper foil layer 73 (see FIGS. 23 and 24). At that time, simultaneously with the removal of the copper foil layers 73, the gold diffusion prevention layers 34, which are in contact with the copper foil layers 73, are also removed. As a result, the terminal pads 30 are exposed, and the gold plating layer 33 of each terminal pad 30 projects from the main face 41.

In a subsequent solder-bump forming step, the solder bumps 54 for IC chip connection are formed on the plurality of terminal pads 30 formed on the outermost resin insulating layer 46. Specifically, after solder balls are placed on the terminal pads 30 by use of an unillustrated solid ball mounting apparatus, the solder balls are heated to a predetermined temperature for reflow, whereby the solder bumps 54 are formed on the terminal pads 30. Similarly, solder bumps 55 are formed on the plurality of pads 53 for BGA formed on the resin insulating layer 43.

After that, the IC chip 21 is mounted on the wiring stacked portion 40 to be located within the IC-chip mounting region 23 (see FIG. 1). At that time, the terminals 22 of the IC chip 21 are aligned with the solder bump 54 on the wiring stacked portion 40. Subsequently, the solder bumps 54 are heated for reflow. As a result, the terminals 22 are joined to the solder bumps 54, and the IC chip 21 is mounted on the wiring stacked portion 40.

Accordingly, the present embodiment provides the effects described below.

(1) According to the exemplary method for manufacturing the multilayer wiring substrate 11 of the present embodiment, after formation of the gold diffusion prevention layer 34 on the copper foil layer 73 in the gold-diffusion-prevention-layer forming step, the gold plating layer 33 is stacked on the gold diffusion prevention layer 34 in the terminal forming step. Therefore, the gold plating layer 33 does not come into direct contact with the copper foil layer 73, and, thus, gold contained in the gold plating layer 33 does not diffuse into the copper which constitutes the copper foil layer 73. As a result, gold, which exhibits excellent joinability with solder, remains on the surface layer (the gold plating layer 33) of each terminal pad 30 without fail. Therefore, each terminal pad 30 and a corresponding solder bump 54 can be joined reliably via the gold plating layer 33. Accordingly, the reliability of connection between the terminal pads 30 and the terminals 22 of the IC chip 21 can be improved, and, thus, the reliability of the multilayer wiring substrate 11 can be improved.

(2) In the present embodiment, as a result of performance of the terminal forming step, the gold diffusion prevention layer 34 and the gold plating layer 33 are provided in each of the recesses 78 formed in the copper foil layer 73. Therefore, upon removal of the copper foil layer 73 and the gold diffusion prevention layer 34 in the metal-layer removing step, the gold plating layer 33 projects from the main face 41 of the wiring stacked portion 40. As a result, as compared with the case where the gold plating layer 33 does not project from the main face 41, the area of contact between each terminal pad 30 and a corresponding solder bump 54 increases. Accordingly, the strength of bonding between the terminal pad 30 and the solder bump 54 can be increased, and, thus, the reliability of connection between the terminal pads 30 and the terminals 22 of the IC chip 21 can be improved further.

Notably, the present embodiment may be modified as follows.

In the above-described embodiment, the wiring stacked portion 40 is formed on each of the opposite sides of the support substrate 70. However, the wiring stacked portion 40 may be formed on only one side of the support substrate 70.

In the above-described embodiment, in addition to the IC chip 21, other electronic components may be mounted on the main face 41 and/or the back face 42 of the wiring stacked portion 40. An example of such an electronic component is a component which has a plurality of terminals on the back face or side face thereof (for example, a transistor, a diode, a resistor, a chip capacitor, a coil, or the like).

Next, technological ideas suggested by the above-described embodiment are enumerated below.

(1) A method for manufacturing a multilayer wiring substrate which has a laminated structure composed of conductor layers and resin insulating layers stacked alternately and in which a plurality of surface connection terminals to which terminals of a chip component are to be surface-connected are formed on a main face of the laminated structure, and a plurality of via conductors connected to the plurality of surface connection terminals are formed in the resin insulating layers, the method comprising: a recess forming step of disposing an etching mask on a copper foil layer, which will be removed later, and half-etching portions of the copper foil layer exposed from opening portions of the mask, so as to form recesses; a nickel-plating-layer forming step of forming, in the recesses, a nickel plating layer for preventing gold from diffusing into copper; a terminal forming step of layering a gold layer, a nickel layer, and a copper layer in this sequence on the nickel plating layer, thereby forming the plurality of surface connection terminals; a resin-insulating-layer forming step of forming, after removal of the mask, the resin insulating layer which covers the surface connection terminals; a conductor forming step of forming the via conductors in each of the resin insulating layers and the conductor layer on each of the resin insulating layers; and a metal-layer removing step of removing the copper foil layer and the nickel plating layer after the conductor forming step so that the gold layer of the plurality of surface connection terminals projects from the main face.

(2) A method for manufacturing a multilayer wiring substrate which has a laminated structure composed of conductor layers and resin insulating layers stacked alternately and in which a plurality of surface connection terminals to which terminals of a chip component are to be surface-connected are formed on a main face of the laminated structure, and a plurality of via conductors connected to the plurality of surface connection terminals are formed in the resin insulating layers, the method comprising: a recess forming step of disposing an etching mask on a copper foil layer, which will be removed later, and half-etching portions of the copper foil layer exposed from opening portions of the mask, so as to form recesses; a gold-diffusion-prevention-layer forming step of forming, in the recesses, a gold diffusion prevention layer for preventing gold from diffusing into copper; a terminal forming step of layering a gold layer, a nickel layer, and a copper layer in this sequence on the gold diffusion prevention layer, thereby forming the plurality of surface connection terminals; a resin-insulating-layer forming step of forming, after removal of the mask, the resin insulating layer which covers the surface connection terminals; a conductor forming step of forming the via conductors in each of the resin insulating layers and the conductor layer on each of the resin insulating layers; and a metal-layer removing step of removing the copper foil layer and the gold diffusion prevention layer after the conductor forming step so that the gold layer of the plurality of surface connection terminals projects from the main face, wherein the projection amount of the gold layer as measured with the main face used as a reference is 5 μm or more.

### DESCRIPTION OF REFERENCE NUMERALS

11: multilayer wiring substrate
21: IC chip which serves as a chip component
22: terminal of the chip component
30: terminal pad which serves as a surface connection terminal
31: copper plating layer which serves as a copper layer
32: nickel plating layer which serves as a nickel layer
33: gold plating layer which serves as a gold layer
34: gold diffusion prevention layer
40: wiring stacked portion which serves as a laminated structure
41: main face of the laminated structure
42: back face of the laminated structure
43, 44, 45, 46: resin insulating layer
51: conductor layer
57: via conductor
58: smaller-diameter-side end face
73: copper foil layer
76: dry film which serves as a mask
77: opening portion of the mask
78: recess

What is claimed is:

1. A method for manufacturing a multilayer wiring substrate which has a laminated structure composed of a plurality of conductor layers and a plurality of resin insulating layers stacked alternately and in which a plurality of surface connection terminals to which terminals of a chip component are to be surface-connected are formed on a main face of the laminated structure, and a plurality of via conductors connected to the plurality of surface connection terminals are formed in the resin insulating layers, the method comprising:
disposing an etching mask on a copper foil layer, and half-etching portions of the copper foil layer exposed from opening portions of the mask, so as to form recesses;
forming, in the recesses, a gold diffusion prevention layer for preventing gold from diffusing into the copper foil layer;
layering a gold layer, a nickel layer, and a copper layer in sequence on the gold diffusion prevention layer, thereby forming the plurality of surface connection terminals;
forming, after removal of the mask, a resin insulating layer which covers the surface connection terminals;
forming the via conductors in each of the plurality of resin insulating layers and forming a conductor layer of said plurality of conductor layers on each of the resin insulating layers; and
removing the copper foil layer and the gold diffusion prevention layer after forming the via conductors so that the gold layer of the plurality of surface connection terminals projects from the main face.

2. A method for manufacturing a multilayer wiring substrate according to claim 1, wherein the gold diffusion prevention layer is formed of a metal which is removed through etching.

3. A method for manufacturing a multilayer wiring substrate according to claim 1, wherein the gold diffusion prevention layer is formed of a metal selected from nickel, palladium, and titanium.

4. A method for manufacturing a multilayer wiring substrate according to claim 1, wherein a depth of the recesses is greater a sum of a thickness of the gold diffusion prevention layer and a thickness of the gold layer.

5. A method for manufacturing a multilayer wiring substrate according to claim 1, wherein the multilayer wiring substrate does not have a core substrate, and each of the via conductors provided in the resin insulating layers has a diameter which increases in the same direction.

6. A multilayer wiring substrate which has a laminated structure composed of conductor layers and resin insulating layers stacked alternately and in which a plurality of surface connection terminals to which terminals of a chip component are to be surface-connected are formed on a main face of the laminated structure, and a plurality of via conductors connected to the plurality of surface connection terminals are formed in the resin insulating layers, wherein each of the plurality of surface connection terminals is composed of a copper layer, a nickel layer, and a gold layer stacked in sequence; and the gold layer projects from the main face of the laminated structure.

7. A multilayer wiring substrate according to claim 6, wherein the plurality of via conductors increase in diameter toward a back face of the laminated structure, and the plurality of surface connection terminals are connected to smaller-diameter-side end faces of the via conductors.
